(19) United States
(12) Patent Application Publication
(10) Pub. No.: US 2025/0138614 A1
(43) Pub. Date: May 1, 2025

(54) STORAGE DEVICE INCLUDING AUXILIARY POWER SUPPLY AND OPERATING METHOD THEREOF

(71) Applicant: SAMSUNG ELECTRONICS CO., LTD., Suwon-si (KR)

(72) Inventors: Kijoong KIM, Suwon-si (KR); Yunseo KANG, Suwon-si (KR); Hojin CHUN, Suwon-si (KR)

(73) Assignee: SAMSUNG ELECTRONICS CO., LTD., Suwon-si (KR)

(21) Appl. No.: 18/903,543

(22) Filed: Oct. 1, 2024

(30) Foreign Application Priority Data
Oct. 25, 2023 (KR) 10-2023-0144174

(51) Int. Cl. G06F 1/30; G06F 1/26

(52) U.S. Cl. CPC G06F 1/30; G06F 1/263

(57) ABSTRACT

An operating method of a storage device, may include: adjusting a value of preset electrical energy to be stored in the auxiliary power supply, based on information about first required energy according to process variability of a main system; adjusting a value of electrical energy to be stored in the auxiliary power supply or a value of second required energy, based on information about the second required energy for a temperature of the main system and a required performance of the main system, to obtain an adjusted value of the electrical energy or an adjusted value of the second required energy; and based on the adjusted value of the electrical energy or the adjusted value of the second required energy being greater than a value of available energy of the auxiliary power supply, outputting a signal indicating that the auxiliary power supply operates in a fail mode.

### CROSS-REFERENCE TO RELATED APPLICATION

This application is based on and claims priority under 35 U.S.C. § 119 to Korean Patent Application No. 10-2023-0144174, filed on Oct. 25, 2023, in the Korean Intellectual Property Office, the disclosure of which is incorporated by reference herein in its entirety.

### BACKGROUND

The present disclosure relates to a storage device, and more particularly, to a storage device including an auxiliary power supply for auxiliary supply of power to the storage device, and an operating method of the storage device.

In general, a memory system including memory devices and a memory controller operates by receiving external power. A sudden power-off (SPO) situation, in which power is suddenly cut off while the memory system is operating, may occur. In this regard, because the memory controller stores data by using a volatile memory, data stored in the volatile memory may be lost, or an operation (e.g., an erase operation, a write operation, etc.) being performed in a memory device may not be completed. To solve this issue, the memory system uses an auxiliary power supply to complete an operation being performed and to perform an operation of backing up data.

### SUMMARY

Example embodiments provide a storage device, which adjusts a value of electrical energy to be stored in an auxiliary power supply according to process variability, a temperature of a main system, and required performance of the main system and, when adjustment is not possible, outputs a signal indicating that the auxiliary power supply is operating in a fail mode, thereby providing high reliability, and an operating method of the storage device.

Aspects of the disclosure are not limited to those mentioned above, and other aspects will be clearly understood by one of ordinary skill in the art from the following description.

According to an aspect of one or more example embodiments, an operating method of a storage device including an auxiliary power supply, includes: adjusting a value of preset electrical energy to be stored in the auxiliary power supply, based on information about first required energy according to process variability of a main system; adjusting a value of electrical energy to be stored in the auxiliary power supply or a value of second required energy, based on information about the second required energy for a temperature of the main system and a required performance of the main system, to obtain an adjusted value of the electrical energy or an adjusted value of the second required energy; and based on the adjusted value of the electrical energy or the adjusted value of the second required energy being greater than a value of available energy of the auxiliary power supply, outputting a signal indicating that the auxiliary power supply operates in a fail mode.

According to an aspect of one or more example embodiments, a storage device includes: an auxiliary power supply configured to provide auxiliary power; a power supply including a power controller configured to output an output voltage based on external power or the auxiliary power; a temperature sensor configured to measure a temperature of a main system; a controller configured to output information about required energy of the main system; and a correction circuit. The correction circuit is configured to: adjust a value of preset electrical energy to be stored in the auxiliary power supply, based on information about first required energy according to process variability of the main system; adjust a value of electrical energy to be stored in the auxiliary power supply or a value of second required energy, based on information about the second required energy for the temperature of the main system and a required performance of the main system, to obtain an adjusted value of the electrical energy or an adjusted value of the second required energy; and based on the adjusted value of the electrical energy or the adjusted value of the second required energy is greater than a value of available energy of the auxiliary power supply, output a signal indicating that the auxiliary power supply operates in a fail mode to the controller.

According to an aspect of one or more example embodiments, a storage device includes: an auxiliary power supply configured to provide auxiliary power; a power supply may include a power controller configured to output an output voltage based on external power or the auxiliary power; a temperature sensor configured to measure a temperature of a main system; the main system configured to operate based on the output voltage and perform a dump operation of backing up data based on a sudden power-off occurring; and a correction circuit. The correction circuit is configured to: adjust a value of preset electrical energy to be stored in the auxiliary power supply, based on information about first required energy according to process variability of the main system; adjust a value of electrical energy to be stored in the auxiliary power supply or a value of second required energy, based on information about the second required energy for the temperature of the main system and a required performance of the main system, to obtain an adjusted value of the electrical energy or an adjusted value of the second required energy; and based on the adjusted value of the electrical energy or the adjusted value of the second required energy being greater than a value of available energy of the auxiliary power supply, output a signal indicating that the auxiliary power supply operates in a fail mode to the main system.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating a storage device according to one or more embodiments;

FIG. 2 is a block diagram illustrating a main system according to one or more embodiments;

FIG. 3 is a block diagram illustrating a power supply according to one or more embodiments;

FIG. 4 is a circuit diagram illustrating an auxiliary power supply according to one or more embodiments;

FIG. 5 is a flowchart illustrating an operating method of a storage device according to one or more embodiments;

FIG. 6A is a diagram illustrating an operation of a storage device according to one or more embodiments;

FIG. 6B is a diagram illustrating an operation of a storage device according to one or more embodiments;

FIG. 7A is a diagram illustrating an operation of a storage device according to one or more embodiments;

FIG. 7B is a diagram illustrating an operation of a storage device according to one or more embodiments;

FIG. 7C is a diagram illustrating an operation of a storage device according to one or more embodiments;

FIG. 8 is a block diagram illustrating a storage system including a storage device, according to one or more embodiments; and

FIG. 9 is a block diagram illustrating a controller according to one or more embodiments.

### DETAILED DESCRIPTION

The above and other aspects, features, and advantages of certain embodiments of the present disclosure will be more apparent from the following description taken in conjunction with the accompanying drawings, in which:

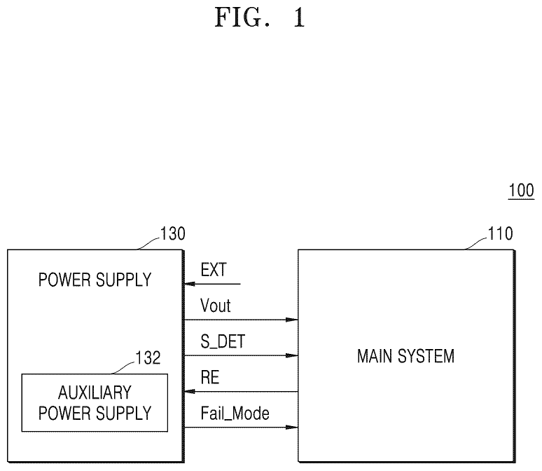

FIG. 1 is a block diagram illustrating a storage device 100 according to one or more embodiments.

Referring to FIG. 1, the storage device 100 may include a solid state drive (SSD). When the storage device 100 includes an SSD, the storage device 100 may correspond to a flash memory device including at least one flash memory chip (e.g., a NAND memory chip) for storing data.

The storage device 100 may include any one of various types of storage devices, such as a multi-media card (MMC), an embedded MMC (eMMC), a reduced-size MMC (RS-MMC) or micro-MMC type multimedia card, a secure digital (SD) card, a mini-SD or micro-SD type SD card, a universal serial bus (USB) storage device, a universal flash storage (UFS) device, a personal computer memory card international association (PCMCIA) card-type storage device, a peripheral component interconnection (PCI) card-type storage device, a PCI-express (PCI-E) card-type storage device, a compact flash (CF) card, a smart media (SM) card, and a memory stick. However, the storage device 100 according to embodiments of the disclosure is not limited to a memory system.

In addition, the storage device 100 may be manufactured as any one of various types of packages. For example, the storage device 100 may be manufactured as any one of various types of packages, such as a package-on-package (POP), a system-in-package (SIP), a system-on-chip (SOC), a multi-chip package (MCP), a chip-on-board (COB), a wafer-level fabricated package (WFP), and a wafer-level stack package (WSP).

The storage device 100 may include a main system 110 and a power supply 130. The power supply 130 may provide an output voltage Vout to the main system 110, and the main system 110 may perform an operation by using the output voltage Vout provided from the power supply 130. The output voltage Vout may refer to a voltage required for the main system 110 to operate. The output voltage Vout may be output to a plurality of channels, and the output voltages Vout output from the respective channels may have the same or different voltage levels.

The main system 110 may control the overall operation of the storage device 100, and may read and write data. The main system 110 may receive a sudden power-off (SPO) detection signal S_DET from the power supply 130, and may control the power supply 130 to operate in an external power supply mode or an auxiliary power supply mode, in response to the SPO detection signal S_DET. In addition, the main system 110 may perform a dump operation for backing up essential information required for system recovery when an SPO occurs.

The power supply 130 may provide the output voltage Vout to the main system 110 by processing external power EXT applied from the outside or auxiliary power applied from an auxiliary power supply 132. The power supply 130 may include at least one power management integrated circuit (PMIC).

The power supply 130 may receive power from the external power EXT, and may detect an SPO by monitoring a voltage level of the external power EXT. For example, the power supply 130 may detect an SPO when the voltage level of the external power EXT falls below an initially-set minimum allowable operating voltage level. The power supply 130 may activate the SPO detection signal S_DET as the SPO is detected, and may output the SPO detection signal S_DET that has been activated to the main system 110. For example, the SPO detection signal S_DET that has been deactivated may be a low-level logic signal, and the SPO detection signal S_DET that has been activated may be a high-level logic signal.

The power supply 130 may include the auxiliary power supply 132. The auxiliary power supply 132 may supply auxiliary power to the main system 110 in an SPO situation. That is, even when the supply of the external power EXT to the main system 110 is interrupted due to the occurrence of an SPO, the auxiliary power may be supplied to the main system 110 by the auxiliary power supply 132. Accordingly, the main system 110 may be driven based on the auxiliary power. In this case, the main system 110 may perform a dump operation based on the auxiliary power supplied by the auxiliary power supply 132. When the dump operation is completed, the main system 110 may normally terminate all operations of the storage device 100.

The power supply 130 may receive information RE about minimum energy required for an operation of the main system 110, and may adjust electrical energy of the auxiliary power provided by the auxiliary power supply 132, based on the information RE about the minimum energy required for the operation of the main system 110. Hereinafter, minimum energy required for a specific operation of the main system 110 (e.g., a read operation, a write operation, or an erase operation) will be referred to as required energy.

The required energy may include first required energy or second required energy. For example, the first required energy may be minimum energy required for the main system 110 to operate in an idle state at a first temperature, and the second required energy may be minimum energy required for the main system 110 to perform a first operation at a second temperature. The first operation may refer to one of specific operations (e.g., a read operation, a write operation, or an erase operation) of the main system 110.

In this regard, the first temperature may be 25 degrees, which represents room temperature, and a value of the second temperature may be greater than a value of the first temperature. In addition, the first required energy may be a value of preset electrical energy to be stored in the auxiliary power supply 132, and in this regard, the value of the preset electrical energy may be a value defined when designing the storage device 100.

In addition, the power supply 130 may receive information about first required energy according to process variability of a semiconductor chip, and may adjust the electrical energy of the auxiliary power provided by the auxiliary power supply 132, based on the information about the first required energy according to the process variability of the semiconductor chip. In this regard, the semiconductor chip may correspond to the storage device 100, a component of the storage device 100 (e.g., the main system 110), or a combination of components of the storage device 100.

Process variability in a semiconductor process may represent variability that occurs during a manufacturing process. Such variability may be caused by various factors, and may affect the quality and performance of a semiconductor chip.

For example, process variability may refer to quantitative process variability or qualitative process variability. Quantitative process variability may refer to numerical variability that occurs during a semiconductor process. For example, quantitative process variability may include variability in physical characteristics, such as length, width, and thickness, of a semiconductor chip. Such quantitative process variability may be affected by factors, such as equipment, materials, temperature, pressure, and time, which occur at specific stages of a manufacturing process. Qualitative process variability may refer to quality-related variability that occurs during a semiconductor process. Qualitative process variability in a semiconductor process may be caused by factors related to product quality, such as defects, errors, and combination rate.

Process variability for first required energy of a semiconductor chip may include variability in first required energy between semiconductor chips shipped within one semiconductor wafer, and may include variability in first required energy between semiconductor chips shipped on different semiconductor wafers. That is, first required energy of one semiconductor chip may vary depending on process variability in a semiconductor process.

In addition, the power supply 130 may receive information about second required energy according to a temperature and required performance of the main system 110, and may adjust the electrical energy of the auxiliary power provided by the auxiliary power supply 132, based on the information about the second required energy according to the temperature and required performance of the main system 110. In this regard, the required performance of the main system 110 may refer to a required throughput or a required operating speed.

When it is not possible to adjust the electrical energy of the auxiliary power provided by the auxiliary power supply 132 in response to the information RE about the minimum energy required for the operation of the main system 110, the power supply 130 may provide a signal Fail_Mode indicating that ‘the auxiliary power supply 132 operates in a fail mode’ to the main system 110.

For example, when the second required energy according to the temperature and required performance of the main system 110 is greater than available energy that the auxiliary power supply 132 may provide, the auxiliary power supply 132 may operate in the fail mode. In this regard, operating in the fail mode may refer to a state in which the power supply 130 is unable to provide the auxiliary power through the auxiliary power supply 132 in an SPO situation. That is, in an SPO situation, all operations of the storage device 100 in the fail mode may be terminated when the external power EXT is not applied thereto.

In this regard, the power supply 130 may provide the signal Fail_Mode indicating that ‘the auxiliary power supply 132 operates in the fail mode’ to the main system 110.

According to one or more embodiments, based on information about first required energy according to process variability, a value of preset electrical energy to be stored in the auxiliary power supply 132 may be adjusted, based on information about second required energy for a temperature and required performance of the main system 110, a value of electrical energy to be stored in the auxiliary power supply 132 or a value of the second required energy may be adjusted, and when the adjusted value of the electrical energy or the adjusted value of the second required energy is greater than a value of available energy of the auxiliary power supply 132, the signal Fail_Mode indicating that ‘the auxiliary power supply 132 operates in a fail mode’ may be provided to the main system 110, thereby improving the reliability of an operation of the storage device 100.

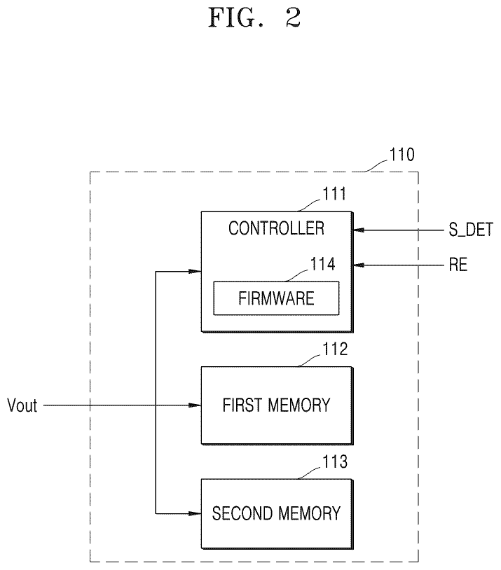

Hereinafter, each component of the storage device 100 will be described in more detail with reference to FIGS. 2 to 7.

FIG. 2 is a block diagram illustrating a main system according to one or more embodiments. In detail, FIG. 2 is a diagram illustrating the main system 110 of FIG. 1. Hereinafter, descriptions will be made with reference to FIG. 1, and redundant descriptions will be omitted.

Referring to FIG. 2, the main system 110 may include a controller 111, a first memory 112, and a second memory 113.

The controller 111 may analyze a signal input to the main system 110, and may process an operation according to a result of the analysis. The controller 111 may control an operation of the power supply 130 (in FIG. 1). For example, the controller 111 may control the power supply 130 (in FIG. 1) to operate in an external power supply mode or an auxiliary power supply mode, in response to the SPO detection signal S_DET received from the power supply 130 (in FIG. 1).

The controller 111 may control operations, such as data read, write, and erase operations, of each of the first memory 112 and the second memory 113. For example, when the power supply 130 (in FIG. 1) operates in the auxiliary power supply mode, the controller 111 may control the first memory 112 and the second memory 113 to perform a dump operation. The dump operation may refer to an operation of backing up essential information required for system recovery.

The controller 111 may include firmware 114. The controller 111 may further include a processor and an operating memory, and the firmware 114 may be a component included in the processor. In one or more embodiments, the controller 111 may include a microcontroller unit (MCU) or a central processing unit (CPU). The firmware 114 may refer to software, an application, etc. that process data in response to a user's input.

The controller 111 may control the overall operation of the storage device 100 by using the firmware 114. The controller 111 may control the power supply 130 (in FIG. 1) by using the firmware 114. However, embodiments are not limited thereto, and the controller 111 may perform an operation of controlling the power supply 130 (in FIG. 1) by using hardware or software.

The firmware 114 may calculate electrical energy required for a specific temperature and specific operation of the main system 110, and may provide information RE about the required energy to the power supply 130 (in FIG. 1). In this regard, the required energy may include first required energy or second required energy. For example, the first required energy may be minimum energy required for the main system 110 to operate in an idle state at a first temperature, and the second required energy may be minimum energy required for the main system 110 to perform a first operation at a second temperature. In this regard, the first temperature may be 25 degrees, which represents room temperature, and a value of the second temperature may be greater than a value of the first temperature. In addition, the first required energy may be a value of preset electrical energy to be stored in the auxiliary power supply 132, and in this regard, the value of the preset electrical energy may be a value defined when designing the storage device 100.

The first memory 112 and the second memory 113 may be different types of memory. One of the first memory 112 and the second memory 113 may be a buffer memory, and the other may be a main memory. For example, the first memory 112 may be a buffer memory, and the second memory 113 may be a main memory. The storage device 100 may be an SSD depending on the type of main memory. For example, when dynamic random-access memory (RAM) (DRAM) is used as a buffer memory for the first memory 112 and a NAND flash memory is used as a main memory for the second memory 113, the storage device 100 may be an SSD device. However, embodiments are not limited to the storage device 100 being an SSD. Hereinafter, the first memory 112 will be described as a buffer memory and the second memory 113 will be described as a main memory, but embodiments are not limited thereto.

The first memory 112 may be used as a data storage medium of the main system 110. The first memory 112 may temporarily store data input/output to/from the second memory 113. Data temporarily stored in the first memory 112 may be transmitted to the second memory 113 under control by the controller 111. The first memory 112 may include a volatile memory. For example, the first memory 112 may include at least one of static RAM (SRAM) and DRAM.

The second memory 113 may be used as a data storage medium of the main system 110. The second memory 113 may include a plurality of nonvolatile memory devices. For example, the second memory 113 may include at least one of non-volatile memories, such as electrically erasable programmable read-only memory (EEPROM), flash memory, phase-change RAM (PRAM), resistance RAM (RRAM), nano-floating gate memory (NFGM), polymer RAM (PoRAM), magnetic RAM (MRAM), and ferroelectric RAM (FRAM). In the following drawings, the second memory 113 is described as a NAND flash memory device, but embodiments are not limited thereto. The second memory 113 may include a memory cell array, a write/read circuit, and control logic.

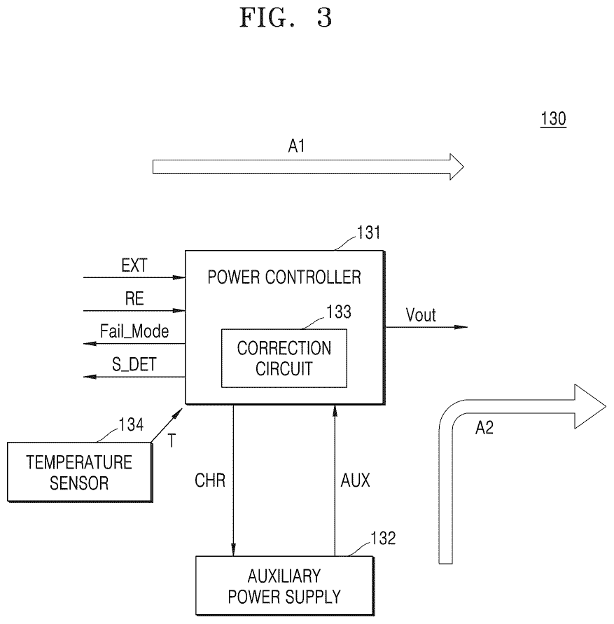

FIG. 3 is a block diagram illustrating a power supply according to one or more embodiments. In detail, FIG. 3 is a diagram illustrating the power supply 130 of FIG. 1. Hereinafter, descriptions will be made with reference to FIGS. 1 and 2, and redundant descriptions will be omitted.

Referring to FIG. 3, the power supply 130 may include a power controller 131, the auxiliary power supply 132, a correction circuit 133, and a temperature sensor 134.

The power controller 131 may control the overall operation of the power supply 130. The power controller 131 may be a power loss protection integrated circuit (PLP IC), but embodiments are not limited thereto.

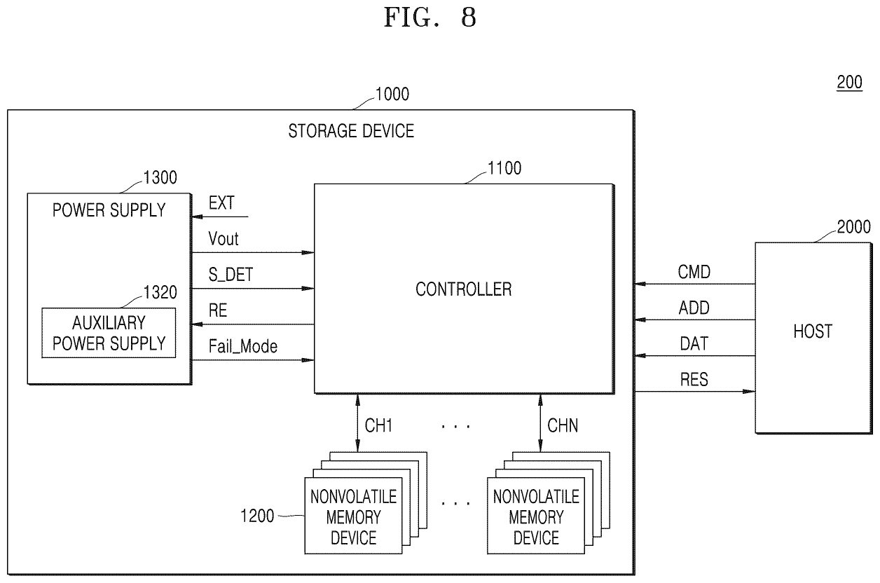

The power controller 131 may receive the external power EXT from the outside, and may convert the external power EXT into the output voltage Vout having a constant voltage level. The external power EXT input to the power controller 131 may be applied from a host 2000 (in FIG. 8), and the output voltage Vout output from the power controller 131 may be converted to have a constant voltage level inside the power controller 131 and provided to the main system 110.

The power controller 131 may monitor the voltage level of the external power EXT, and when the voltage level of the external power EXT falls below the initially-set minimum allowable operating voltage level, the power controller 131 may detect that an SPO has occurred. The power controller 131 may activate the SPO detection signal S_DET as the SPO is detected, and may output the SPO detection signal S_DET that has been activated to the controller 111 (in FIG. 2).

The power controller 131 may operate in an external power supply mode or an auxiliary power supply mode based on the monitored voltage level of the external power EXT. The controller 111 (in FIG. 2) may control the power controller 131 to operate in the external power supply mode or the auxiliary power supply mode, based on the SPO detection signal S_DET output from the power controller 131.

When the external power EXT is normally supplied to the power controller 131, the power controller 131 may deactivate the SPO detection signal S_DET, and the controller 111 (in FIG. 2) may control the power controller 131 to operate in the external power supply mode. Accordingly, the power controller 131 may allow the external power EXT to be output as the output voltage Vout having a constant voltage level, and may block electrical energy (i.e., auxiliary power AUX) charged in the auxiliary power supply 132 from being output as the output voltage Vout. That is, in the external power supply mode, as shown by a first arrow A1, the external power EXT may be provided to the correction circuit 133 as the output voltage Vout.

When the power controller 131 operates in the external power supply mode, the power controller 131 may provide charging power CHR to the auxiliary power supply 132 by using the external power EXT. That is, the power controller 131 may convert the external power EXT into the charging power CHR required for charging the auxiliary power supply 132, and may provide the charging power CHR to the auxiliary power supply 132.

Hereinafter, the case in which the external power EXT is normally supplied to the power controller 131 may refer to a case in which the voltage level of the external power EXT is equal to or higher than the initially-set minimum allowable operating voltage level. In addition, the case in which the external power EXT is not normally supplied to the power controller 131 may refer to a case in which the voltage level of the external power EXT falls below the initially-set minimum allowable operating voltage level. For example, in an SPO situation, the external power EXT may not be normally supplied to the power controller 131.

When the external power EXT is not normally supplied to the power controller 131, the power controller 131 may activate the SPO detection signal S_DET, and the controller 111 (in FIG. 2) may control the power controller 131 to operate in the auxiliary power supply mode. In this case, the power controller 131 may block the external power EXT from being output as the output voltage Vout, and may allow the electrical energy (i.e., the auxiliary power AUX) charged in the auxiliary power supply 132 to be output as the output voltage Vout. That is, in the auxiliary power supply mode, as shown by a second arrow A2, the auxiliary power AUX provided from the auxiliary power supply 132 may be supplied to the main system 110 as the output voltage Vout.

The auxiliary power supply 132 may include one or more capacitors. The auxiliary power supply 132 may store electrical energy by using the charging power CHR supplied from the power controller 131. In addition, the auxiliary power supply 132 may provide the electrical energy stored in the auxiliary power supply 132 to the power controller 131 as the auxiliary power AUX. The power controller 131 may convert the auxiliary power AUX such that the auxiliary power AUX has a constant voltage level, and may provide the auxiliary power AUX that has been converted to the main system 110 as the output voltage Vout. Accordingly, even when an SPO situation occurs, the storage device 100 (in FIG. 1) may perform data backup, and may normally terminate an operation being performed.

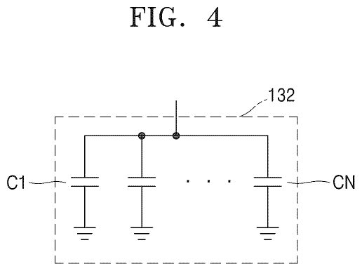

Although the auxiliary power supply 132 is shown as a separate block from the power controller 131 in FIG. 3, embodiments are not limited thereto, and the auxiliary power supply 132 may be a component included in the power controller 131. The auxiliary power supply 132 will be described in more detail below with reference to FIG. 4.

The correction circuit 133 may monitor a value of electrical energy to be stored in the auxiliary power supply 132 in real time, and may adjust a value of required energy or a value of electrical energy to be stored in the auxiliary power supply 132.

The correction circuit 133 may receive the information RE about required energy for a specific temperature and specific operation of the main system 110 from the firmware 114 (in FIG. 2), and may adjust a value of electrical energy to be stored in the auxiliary power supply 132. For example, the correction circuit 133 may adjust the value of the electrical energy to be stored in the auxiliary power supply 132 by changing a level of a charging voltage of the auxiliary power supply 132.

In addition, the correction circuit 133 may receive the information RE about required energy for a specific temperature and specific operation of the main system 110 from the firmware 114 (in FIG. 2), and may reduce a value of the required energy by adjusting a level of a voltage required for a load included in the main system 110.

In addition, the correction circuit 133 may request information about required energy for a specific temperature from the main system 110, based on temperature measurement information of the temperature sensor 134.

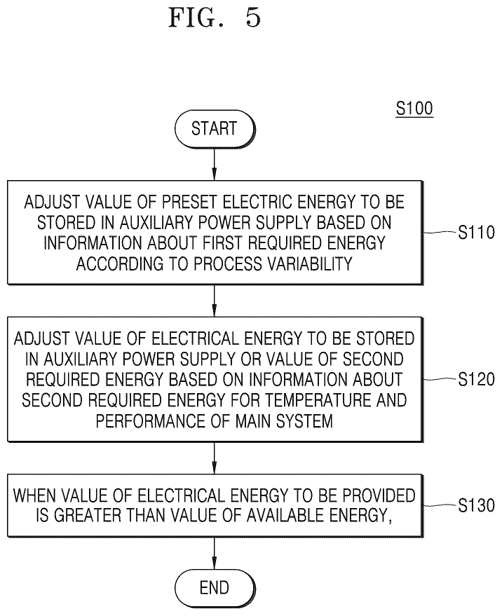

An operation of the correction circuit 133 will be described in more detail below with reference to FIGS. 5 to 7.

The temperature sensor 134 may measure a temperature of the storage device 100 or a component included in the storage device 100. The temperature sensor 134 may operate inside the storage device 100, or may be installed separately outside the storage device 100 and transmit measured data to the storage device 100. The temperature sensor 134 may periodically transmit measured temperature data to the storage device 100 or the correction circuit 133 for monitoring, and when a measured temperature exceeds a reference temperature, the temperature sensor 134 may generate an event signal and transmit the event signal to the storage device 100 or the correction circuit 133. In this regard, a measurement target may be, for example, a semiconductor chip included in the storage device 100 to perform a specific operation. For example, the semiconductor chip may correspond to the storage device 100, a component of the storage device 100 (e.g., the main system 110), or a combination of components of the storage device 100.

FIG. 4 is a circuit diagram illustrating an auxiliary power supply according to one or more embodiments. In detail, FIG. 4 is a circuit diagram illustrating the auxiliary power supply 132 of FIG. 3. Hereinafter, descriptions will be made with reference to FIGS. 1 to 3, and redundant descriptions will be omitted.

Referring to FIG. 4, the auxiliary power supply 132 may include at least one capacitor C1 to CN. The auxiliary power supply 132 may have a structure in which the at least one capacitor C1 to CN is connected in parallel. The at least one capacitor C1 to CN may include a high-capacity capacitor, for example, a super capacitor. The super capacitor may be a power storage device capable of storing a large amount of charge. The at least one capacitor C1 to CN may include at least one of an electrolytic capacitor, a tantalum capacitor, a film capacitor, and a ceramic capacitor.

In the electrolytic capacitor, a thin oxide film may be used as a dielectric, and aluminum may be used as an electrode. The electrolytic capacitor may have good low-frequency characteristics, and may be implemented with a high capacity up to tens of thousands of μF. The tantalum capacitor may have an electrode formed of tantalum (Ta), and may have better temperature and frequency characteristics than the electrolytic capacitor. The film capacitor may have a structure in which a film dielectric, such as polypropylene, polystyrol, or Teflon, is placed between electrodes, such as aluminum and copper, and wound into a roll. Film capacitors may have different capacities and uses depending on materials and manufacturing processes. In the ceramic capacitor, a material having a high dielectric constant, such as titanium-barium, may be used as a dielectric. The ceramic capacitor may have good high-frequency characteristics, and may be used to pass noise to the ground. In a multi-layer ceramic condenser (MLCC), which is a type of ceramic capacitor, a multi-layered high-k ceramic may be used as a dielectric between electrodes. The MLCC may have good temperature and frequency characteristics and a small size, and thus may be widely used for bypass.

The at least one capacitor C1 to CN constituting the auxiliary power supply 132 of the present embodiment may include an aluminum capacitor, a tantalum capacitor, or an MLCC, each having a low equivalent series resistance (ESR), but embodiments are not limited thereto. As described above with reference to FIG. 3, the auxiliary power supply 132 may be charged by the charging power CHR (in FIG. 3) provided through the power controller 131, and the charging power CHR (in FIG. 3) may be provided based on the external power EXT (in FIG. 3).

Electrical energy stored in the auxiliary power supply 132 may be calculated according to Equation 1 below.

$${E}_{CAP} = \frac{1}{2} {CV}_{CHR}^{2} \qquad [ Equation 1 ]$$

In this regard, E_{CAP} may be electrical energy stored in the auxiliary power supply 132, C may be an equivalent capacitance of the auxiliary power supply 132, and V_{CHR} may be a charging voltage of the auxiliary power supply 132. Hereinafter, the ‘capacitance of the auxiliary power supply 132’ may refer to an equivalent capacitance of the at least one capacitor C1 to CN included in the auxiliary power supply 132. The charging voltage V_{CHR} of the auxiliary power supply 132 may be a value that is variable by the correction circuit 133.

In addition, the capacitance of the at least one capacitor C1 to CN may be a variable value, and may be measured in real time by monitoring the auxiliary power supply 132 in the main system 110 (in FIG. 1). Accordingly, a user may know a value of the electrical energy E_{CAP} charged in the auxiliary power supply 132 in real time. As the capacitance of the auxiliary power supply 132 decreases, the electrical energy stored in the auxiliary power supply 132 may decrease. As the auxiliary power supply 132 is used, the capacitance thereof may decrease, and thus, a voltage level of the auxiliary power AUX provided by the auxiliary power supply 132 may decrease.

FIG. 5 is a flowchart illustrating an operating method of a storage device according to one or more embodiments. In detail, FIG. 5 is a flowchart illustrating an operating method S100 of the storage device 100 in FIG. 1. Hereinafter, descriptions will be made with reference to FIGS. 1 to 4, and redundant descriptions will be omitted.

Referring to FIG. 5, the operating method S100 of the storage device 100 may include operations S110, S120, and S130.

In operation S110, the correction circuit 133 (in FIG. 3) may receive information RE about first required energy according to process variability, and may adjust a value of preset electrical energy to be stored in the auxiliary power supply 132 (in FIG. 1), based on the information RE about the first required energy according to process variability.

In this regard, the information RE about the first required energy according to process variability may include a largest value among values of a plurality of first required energies according to process variability. In addition, the value of the preset electrical energy to be stored in the auxiliary power supply 132 (in FIG. 1) may be a value defined when designing the storage device 100, and the first required energy may be minimum energy required for the main system 110 (in FIG. 1) to operate in an idle state at a first temperature.

The information RE about the process variability for the first required energy may be stored in advance in the firmware 114 (in FIG. 2), and the firmware 114 (in FIG. 2) may provide the largest value among the values of the plurality of first required energies to the correction circuit 133 (in FIG. 3), based on the information RE about the process variability for the first required energy.

In operation S120, the correction circuit 133 (in FIG. 3) may receive information RE about second required energy for a temperature and required performance of the main system 110 (in FIG. 1), and may adjust a value of electrical energy to be stored in the auxiliary power supply 132 (in FIG. 1) or a value of the second required energy, based on the information RE about the second required energy for the temperature and performance of the main system 110 (in FIG. 1).

The firmware 114 (in FIG. 2) may calculate electrical energy required for a specific temperature and specific operation of the main system 110 (in FIG. 1), and may provide information RE about the required energy to the correction circuit 133 (in FIG. 3). In this regard, the firmware 114 (in FIG. 2) may provide the correction circuit 133 (in FIG. 3) with the information RE about the second required energy, which is minimum energy required for the main system 110 (in FIG. 1) to perform a first operation at a second temperature. In addition, a value of the second temperature may be greater than a value of the first temperature of the first required energy.

In operation S130, when the value of the electrical energy or the value of the second required energy that has been adjusted based on the information RE about the second required energy is greater than a value of available energy of the auxiliary power supply 132 (in FIG. 1), the correction circuit 133 (in FIG. 3) may provide a signal Fail_Mode (in FIG. 1) indicating that ‘the auxiliary power supply 132 (in FIG. 1) operates in a fail mode’ to the main system 110 (in FIG. 1).

In this regard, operating in the fail mode may refer to a state in which the power supply 130 (in FIG. 1) is unable to provide the auxiliary power through the auxiliary power supply 132 (in FIG. 1) in an SPO situation. That is, in an SPO situation, all operations of the storage device 100 (in FIG. 1) in the fail mode may be terminated when external power EXT is not applied thereto.

By notifying a user that the auxiliary power supply 132 (in FIG. 1) of the storage device 100 is operating in the fail mode, the user's confidence in an operation of the storage device 100 may be increased.

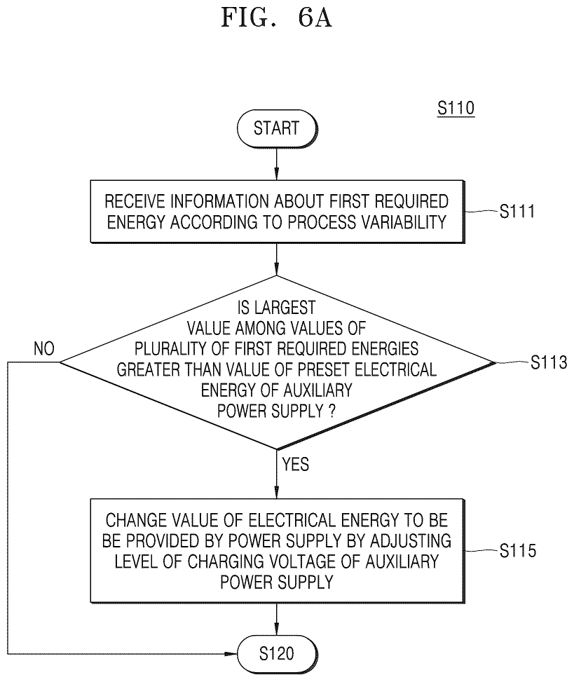

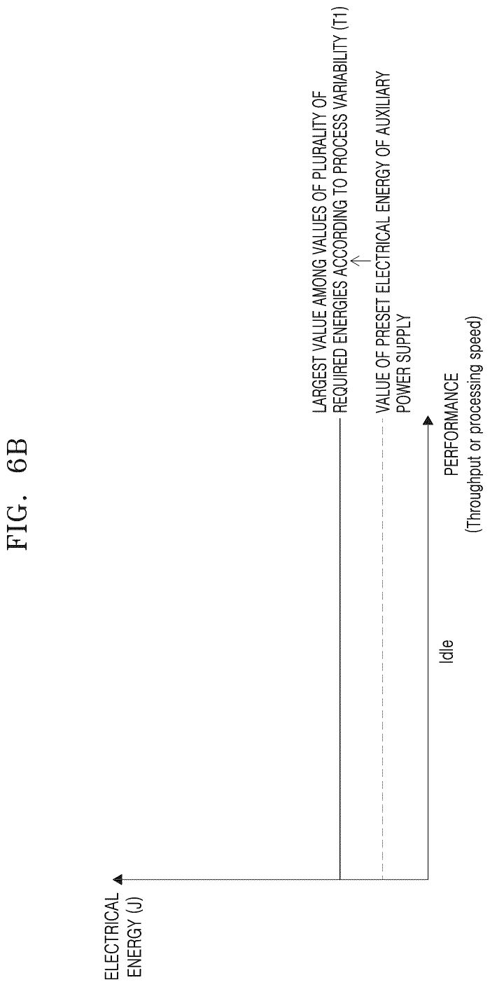

FIGS. 6A and 6B are diagrams illustrating an operation of a storage device according to one or more embodiments. In detail, FIG. 6A is a flowchart illustrating operation S110 of FIG. 5 in more detail, and FIG. 6B is a diagram illustrating a change in value of the preset electrical energy to be stored in the auxiliary power supply 132 (in FIG. 1).

Referring to FIG. 6A, operation S110 of FIG. 5 may include operations S111, S113, and S115.

In operation S111, the correction circuit 133 (in FIG. 3) may receive the information RE about the first required energy according to process variability from the firmware 114 (in FIG. 2). The information RE about the first required energy according to process variability may include a largest value among values of a plurality of first required energies according to process variability. Process variability in a semiconductor process may represent variability that occurs during a manufacturing process, and such variability may also appear in the first required energy. The first required energy may be minimum energy required for the main system 110 (in FIG. 1) to operate in an idle state at a first temperature T1.

In operation S113, the correction circuit 133 (in FIG. 3) may compare the largest value among the values of the plurality of first required energies according to process variability with the value of the preset electrical energy to be stored in the auxiliary power supply 132 (in FIG. 1). In this regard, the value of the preset electrical energy to be stored in the auxiliary power supply 132 (in FIG. 1) may be a value defined when designing the main system 110 (in FIG. 1).

In operation S113, when the largest value among the values of the plurality of first required energies according to process variability is not greater than the value of the preset electrical energy to be stored in the auxiliary power supply 132 (in FIG. 1), operation S120 may proceed.

In operation S115, when the largest value among the values of the plurality of first required energies according to process variability is greater than the value of the preset electrical energy to be stored in the auxiliary power supply 132 (in FIG. 1), the correction circuit 133 (in FIG. 3) may change the value of the electrical energy to be stored in the auxiliary power supply 132 (in FIG. 1) by adjusting the charging voltage V_{CHR} (in Equation 1) of the auxiliary power supply 132 (in FIG. 1).

For example, by increasing a level of the charging voltage V_{CHR} (in Equation 1) of the auxiliary power supply 132 (in FIG. 1), the correction circuit 133 (in FIG. 3) may increase the value of the electrical energy to be stored in the auxiliary power supply 132 (in FIG. 1).

FIG. 6B is a diagram illustrating the electrical energy to be stored in the auxiliary power supply 132 (in FIG. 1) according to the performance of the main system 110 (in FIG. 1), according to the embodiment of FIG. 6A. In this regard, the main system 110 (in FIG. 1) may be in a state before being shipped within a semiconductor wafer. In addition, the performance of the main system 110 (in FIG. 1) may refer to a required throughput or a required operating speed, and FIG. 6B shows the electrical energy to be stored in the auxiliary power supply 132 (in FIG. 1) according to the performance of the main system 110 (in FIG. 1) in the idle state at the first temperature T1.

Referring to FIG. 6B, when a largest value E1 among values of a plurality of required energies according to process variability is greater than the value of the preset electrical energy to be stored in the auxiliary power supply 132 (in FIG. 1), the correction circuit 133 (in FIG. 3) may change the value of the electrical energy to be stored in the auxiliary power supply 132 (in FIG. 1) to the largest value E1 among the values of the plurality of required energies according to process variability by adjusting the charging voltage V_{CHR} (in Equation 1) of the auxiliary power supply 132 (in FIG. 1).

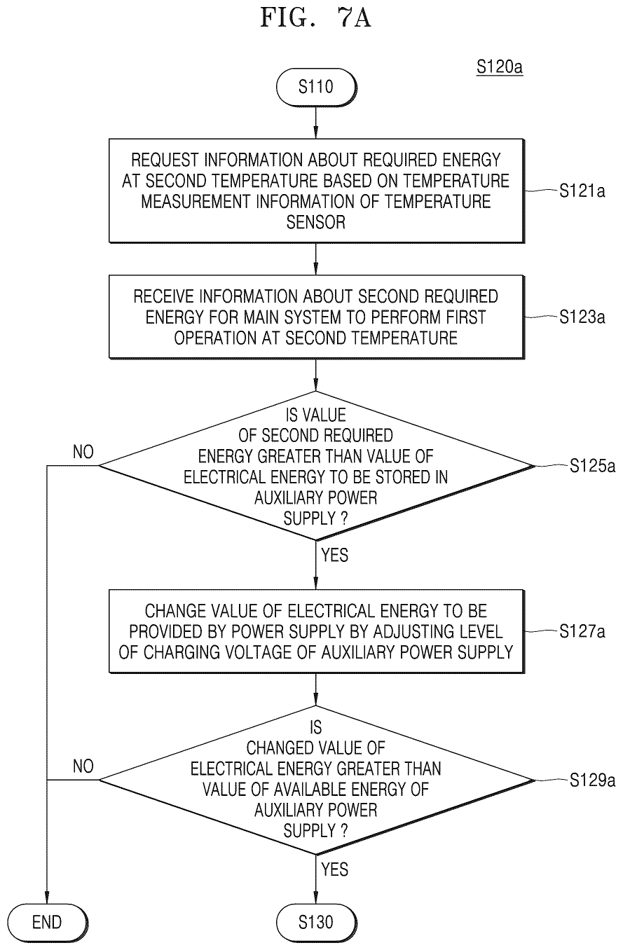

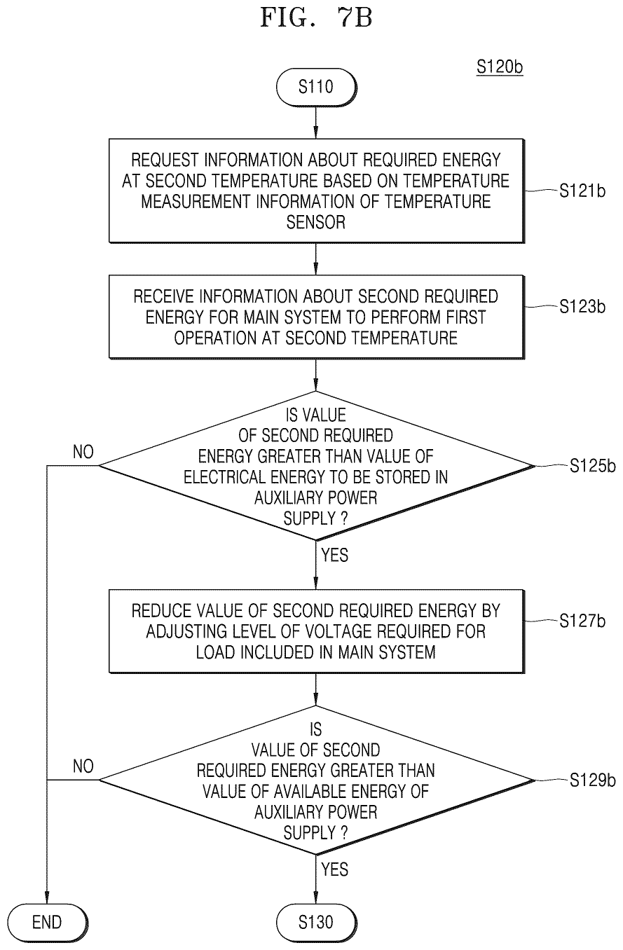

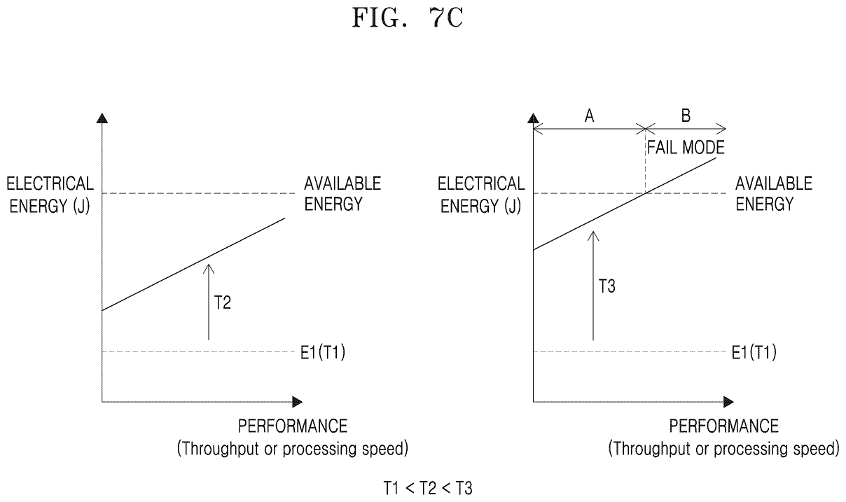

FIGS. 7A, 7B, and 7C are diagrams illustrating an operation of a storage device according to embodiments. In detail, FIGS. 7A and 7B are flowcharts illustrating operation S120 of FIG. 5 in more detail, and FIG. 7C is a diagram illustrating a change in value of the electrical energy to be stored in the auxiliary power supply 132 (in FIG. 1), according to the embodiment of FIG. 7A.

Referring to FIGS. 7A and 7B, operation S120 of FIG. 5 may include operation S120a or operation S120b. Referring to FIG. 7A, operation S120a may include operations S121a, S123a, S125a, and S127a. Referring to FIG. 7B, operation S120b may include operations S121b, S123b, S125b, and S127b. Because FIGS. 7A and 7B differ only with regard to operations S125a and S125b, and S127a and S127b, FIGS. 7A and 7B will be described together, and only differences therebetween will be described separately.

In operation S121a and operation S121b, the correction circuit 133 (in FIG. 3) may request information about required energy for the second temperature from the main system 110 (in FIG. 1), based on temperature measurement information of the temperature sensor 134 (in FIG. 3). In this regard, when a temperature value of a measurement target included in the temperature measurement information is equal to or greater than a reference value, the correction circuit 133 (in FIG. 3) may request information about required energy for a specific temperature (e.g., the reference value) from the main system 110 (in FIG. 1). In addition, in response to the request from the correction circuit 133 (in FIG. 3), the main system 110 (in FIG. 1) may provide the correction circuit 133 (in FIG. 3) with information about the second required energy, which is required to perform a specific operation at a specific temperature.

In one or more embodiments, the correction circuit 133 (in FIG. 3) may compare the second temperature, which is a temperature value of a measurement target included in the temperature measurement information, with a first reference temperature. In this regard, the first reference temperature may be a temperature value higher than room temperature (e.g., 25 degrees). That is, the first reference temperature may be a reference value for distinguishing between high temperature and room temperature. When the second temperature is higher than the first reference temperature, the correction circuit 133 (in FIG. 3) may request information about required energy of the main system 110 (in FIG. 1) at the second temperature from the main system 110 (in FIG. 1). In response to the above-described request, the main system 110 (in FIG. 1) may provide the information about the second required energy, which is the minimum energy required for the main system 110 (in FIG. 1) to perform the first operation at the second temperature, to the correction circuit 133 (in FIG. 3).

In this regard, minimum energy required (i.e., required energy) for an operation of the main system 110 (in FIG. 1) may vary depending on performance (e.g., a throughput or an operating speed) required for a specific operation (e.g., a read operation, a write operation, or an erase operation) of the main system 110 (in FIG. 1). The first operation may refer to one of specific operations (e.g., a read operation, a write operation, or an erase operation) of the main system 110 (in FIG. 1).

In operation S123a and operation S123b, the correction circuit 133 (in FIG. 3) may receive the information about the second required energy, which is the minimum energy required for the main system 110 (in FIG. 1) to perform the first operation at the second temperature.

In operation S125a and operation S125b, the correction circuit 133 (in FIG. 3) may compare the value of the second required energy with the value of the electrical energy to be stored in the auxiliary power supply 132 (in FIG. 1). In this regard, when the value of the second required energy is not greater than the value of the electrical energy to be stored in the auxiliary power supply 132 (in FIG. 1), the operation may be terminated.

Hereinafter, FIGS. 7A and 7B will be described separately.

Referring to FIG. 7A, in operation S127a, when the value of the second required energy is greater than the value of the electrical energy to be stored in the auxiliary power supply 132 (in FIG. 1), the correction circuit 133 (in FIG. 3) may increase the value of the electrical energy to be stored in the auxiliary power supply 132 (in FIG. 1) to correspond to the value of the second required energy by adjusting the charging voltage V_{CHR} (in Equation 1) of the auxiliary power supply 132 (in FIG. 1).

For example, by increasing a level of the charging voltage V_{CHR} (in Equation 1) of the auxiliary power supply 132 (in FIG. 1), the correction circuit 133 (in FIG. 3) may increase the value of the electrical energy to be stored in the auxiliary power supply 132 (in FIG. 1) to correspond to the value of the second required energy.

In operation S129a, the correction circuit 133 (in FIG. 3) may compare the changed value of the electrical energy to be stored in the auxiliary power supply 132 (in FIG. 1) with a value of available energy, which is maximum electrical energy that the auxiliary power supply 132 (in FIG. 1) may provide. When the changed value of the electrical energy is not greater than the value of the available energy, the operation may be terminated.

In operation S129a, when the changed value of the electrical energy is greater than the value of the available energy, operation S130 may proceed. That is, when the changed value of the electrical energy is greater than the value of the available energy, the correction circuit 133 (in FIG. 3) may provide the signal Fail_Mode (in FIG. 1) indicating that ‘the auxiliary power supply 132 (in FIG. 1) operates in the fail mode’ to the main system 110 (in FIG. 1).

Referring to FIG. 7B, in operation S127b, when the value of the second required energy is greater than the value of the electrical energy to be stored in the auxiliary power supply 132 (in FIG. 1), the correction circuit 133 (in FIG. 3) may reduce the value of the second required energy by adjusting a level of a voltage required for a load included in the main system 110 (in FIG. 1). For example, an output current or an output voltage may be reduced by reducing a voltage level between a gate and a source of a transistor included in a load of the main system 110 (in FIG. 1). As a result, the second required energy may be reduced.

In operation S129b, the correction circuit 133 (in FIG. 3) may compare the reduced value of the second required energy with a value of available energy, which is maximum electrical energy that the auxiliary power supply 132 (in FIG. 1) may provide. When the reduced value of the second required energy is not greater than the value of the available energy, the operation may be terminated.

In operation S129b, when the reduced value of the second required energy is greater than the value of the available energy, operation S130 may proceed. That is, when the reduced value of the second required energy is greater than the value of the available energy, the correction circuit 133 (in FIG. 3) may provide the signal Fail_Mode (in FIG. 1) indicating that ‘the auxiliary power supply 132 (in FIG. 1) operates in the fail mode’ to the main system 110 (in FIG. 1).

The available energy of the auxiliary power supply 132 (in FIG. 1) may be determined by Equation 1 described above, and may refer to a case in which the level of the charging voltage V_{CHR} (in Equation 1) has a maximum value due to the correction circuit 133 (in FIG. 3).

FIG. 7C is a diagram illustrating the second required energy according to the performance of the main system 110 (in FIG. 1), according to the embodiment of FIG. 7A. In this regard, the main system 110 (in FIG. 1) may be in a state after being shipped within a semiconductor wafer. In addition, the performance of the main system 110 (in FIG. 1) may refer to a required throughput or a required operating speed according to specific operations (e.g., a read operation, a write operation, or an erase operation).

Referring to FIG. 7C, E1, which is the value of the electrical energy to be stored in the auxiliary power supply 132 (in FIG. 1) according to the performance of the main system 110 (in FIG. 1) in the idle state at the first temperature T1, as described in FIG. 6B, is shown. In this regard, E1 may be a largest value among values of a plurality of required energies according to process variability. In addition, a value of the second required energy according to the performance of the main system 110 (in FIG. 1) at a second temperature T2 and a value of the second required energy according to the performance of the main system 110 (in FIG. 1) at a third temperature T3 are shown. Descriptions will be made assuming that temperature values increase in the order of the first temperature T1, the second temperature T2, and the third temperature T3.

Referring to FIG. 7C, the value of the second required energy according to the performance of the main system 110 (in FIG. 1) at the second temperature T2 may be increased according to required performance corresponding to the first operation. In addition, because all values of the second required energy are less than the value of the available energy of the auxiliary power supply 132 (in FIG. 1), the value of the electrical energy to be stored in the auxiliary power supply 132 (in FIG. 1) may be increased by the correction circuit 133 (in FIG. 3) corresponding to the second required energy.

Referring to FIG. 7C, the value of the second required energy according to the performance of the main system 110 (in FIG. 1) at the third temperature T3 may be increased according to required performance corresponding to the first operation. In interval A, because all values of the second required energy are less than the value of the available energy of the auxiliary power supply 132 (in FIG. 1), the value of the electrical energy to be stored in the auxiliary power supply 132 (in FIG. 1) may be increased by the correction circuit 133 (in FIG. 3) corresponding to the second required energy. In contrast, in interval B, because all values of the second required energy are greater than the value of the available energy of the auxiliary power supply 132 (in FIG. 1), the value of the electrical energy to be stored in the auxiliary power supply 132 (in FIG. 1) may not be increased by the correction circuit 133 (in FIG. 3) corresponding to the second required energy. Accordingly, in interval B, the auxiliary power supply 132 (in FIG. 1) may operate in the fail mode, and thus, the correction circuit 133 (in FIG. 3) may provide the signal Fail_Mode (in FIG. 1) indicating that ‘the auxiliary power supply 132 (in FIG. 1) operates in the fail mode’ to the main system 110 in (FIG. 1).

In a comparative example, a value of electrical energy to be stored in the auxiliary power supply 132 (in FIG. 1) under the room temperature standard is fixed to a value defined at the time of design, and the value of the electrical energy to be stored in the auxiliary power supply 132 (in FIG. 1) is not adjusted according to process variability, a temperature of the main system 110 (FIG. 1), and required performance of the main system 110 (FIG. 1). In contrast, according to the disclosure, a value of electrical energy to be stored in the auxiliary power supply 132 (in FIG. 1) may be changed step by step to correspond to required energy according to process variability, a temperature of the main system 110 (FIG. 1), and required performance of the main system 110 (FIG. 1).

In addition, in the comparative example, criteria for operating in a fail mode have been limited to cases in which a capacitance of the auxiliary power supply 132 (in FIG. 1), which decreases with usage time, reaches a preset value. According to the disclosure, a case in which a value of electrical energy to be stored in the auxiliary power supply 132 (in FIG. 1) is greater than a value of available energy or a case in which a reduced value of required energy is greater than a value of available energy has been added to criteria for the storage device 100 to operate in a fail mode.

As a result, by notifying a user that the auxiliary power supply 132 (in FIG. 1) of the storage device 100 is operating in the fail mode, the user's confidence in an operation of the storage device 100 may be increased even in the above-described case.

FIG. 8 is a block diagram illustrating a storage system 200 including a storage device, according to one or more embodiments.

Referring to FIG. 8, the storage system 200 may include a storage device 1000 and a host 2000. The storage device 1000 may provide data in response to a request from the host 2000. For example, the storage device 1000 may store data provided from the host 2000, or may provide data stored in the storage device 1000 to the host 2000.

The storage device 1000 may include the storage device 100 of FIG. 1. The storage device 1000 may include an SSD. The storage device 1000 may include a controller 1100, a plurality of nonvolatile memory devices 1200, and a power supply 1300.

The controller 1100 may transmit/receive a signal to/from the host 2000. In this regard, the signal may include a command CMD, an address ADD, data DAT, etc. For example, the command CMD may include a write command for writing data to the storage device 1000 and a read command for reading data stored in the storage device 1000. That is, the controller 1100 may receive a write command and a read command from the host 2000.

The controller 1100 may control the overall operation of the storage device 1000 based on a signal received from the host 2000. The controller 1100 may control firmware or software for driving the storage device 1000, based on the command CMD received from the host 2000. For example, when the command CMD provided from the host 2000 is a write command, the controller 1100 may control the storage device 1000 to write data by processing the write command. For example, when the command CMD provided from the host 2000 is a read command, the controller 1100 may control the storage device 1000 to read data by processing the read command.

The controller 1100 may receive an output voltage Vout from the power supply 1300. The output voltage Vout may be a voltage required for the controller 1100 and the plurality of nonvolatile memory devices 1200 to operate. The output voltage Vout may be output to a plurality of channels CH1 to CHN, and the output voltages Vout output from the channels CH1 to CHN may have different voltage levels.

The controller 1100 may receive an SPO detection signal S_DET from the power supply 1300, and may control the power supply 1300 to operate in an external power supply mode or an auxiliary power supply mode, in response to the SPO detection signal S_DET. In addition, the controller 1100 may control an operation of the nonvolatile memory device 1200 such that the nonvolatile memory device 1200 performs a dump operation in an SPO situation.

The power supply 1300 may receive information RE about minimum energy required for an operation of the storage device 1000 from the controller 1100, and may adjust electrical energy of auxiliary power provided by an auxiliary power supply 1320, based on the information RE about the minimum energy required for the operation of the storage device 1000.

When it is not possible to adjust the electrical energy of the auxiliary power provided by the auxiliary power supply 1320 in response to the information RE about the minimum energy required for the operation of the storage device 1000, the power supply 1300 may provide a signal Fail_Mode indicating that ‘the auxiliary power supply 1320 operates in a fail mode’ to the controller 1100.

The controller 1100 may generate a response signal RES according to an operation, and may transmit the response signal RES that has been generated to the host 2000. The response signal RES may refer to a signal generated based on a result of the controller 1100 processing the operation of the storage device 1000 in response to the command CMD. The controller 1100 may provide the response signal RES to the host 2000.

The nonvolatile memory devices 1200 may be used as a storage medium of the storage device 1000. The nonvolatile memory devices 1200 may include a NAND flash memory device, but embodiments are not limited thereto. The nonvolatile memory devices 1200 may include a memory cell array, a write/read circuit, and control logic. The nonvolatile memory devices 1200 may include the second memory 113 of FIG. 2.

The power supply 1300 may process external power EXT applied from the outside or the auxiliary power applied from the auxiliary power supply 1320, and may provide the processed power to the storage device 1000. The power supply 1300 may detect an SPO by monitoring a voltage level of the external power EXT. When an SPO occurs, the power supply 1300 may activate the SPO detection signal S_DET, and may output the SPO detection signal S_DET that has been activated to the controller 1100. The power supply 1300 may include the power supply 130 of FIG. 3. The power supply 1300 may include the auxiliary power supply 1320.

The host 2000 may be configured in the form of a board, such as a printed circuit board. The host 2000 may include background function blocks for generating and processing control signals. The host 2000 may include a connection terminal, such as a socket, a slot, or a connector, for transmitting/receiving a signal to/from the storage device 1000, and the storage device 1000 may be mounted on the connection terminal of the host 2000. The host 2000 and the storage device 1000 may transmit signals, such as a command, an address, and data, through the connection terminal. The connection terminal may be configured in various forms based on an interface method between the host 2000 and the storage device 1000.

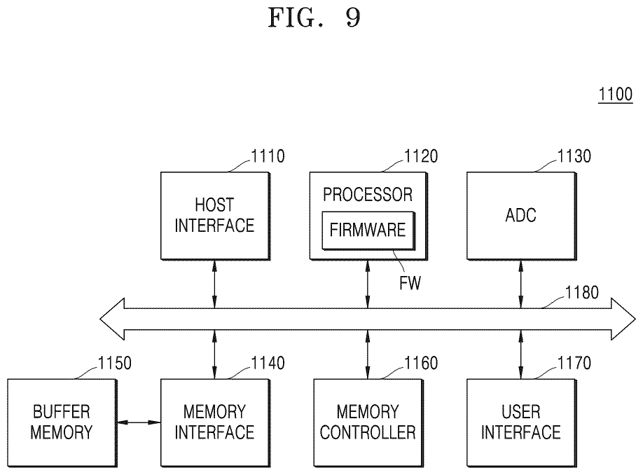

Hereinafter, the controller 1100 will be described in more detail with reference to FIG. 9.

FIG. 9 is a block diagram illustrating a controller according to one or more embodiments. In detail, FIG. 9 is a diagram illustrating the controller 1100 of FIG. 8. Hereinafter, descriptions will be made with reference to FIG. 8, and redundant descriptions will be omitted.

Referring to FIG. 9, the controller 1100 may include a host interface 1110, a processor 1120, an analog-to-digital converter (ADC) 1130, a memory interface 1140, a buffer memory 1150, a memory controller 1160, a user interface 1170, and a bus 1180.

The host interface 1110 may control an interface operation between the storage device 1000 (in FIG. 8) and the host 2000 (in FIG. 8). The host interface 1110 may interconnect the storage device 1000 (in FIG. 8) and the host 2000 (in FIG. 8) connected to the storage device 1000 (in FIG. 8), and may include a data exchange protocol between the storage device 1000 (in FIG. 8) and the host 2000 (in FIG. 8). The host interface 1110 may include a serial advanced technology attachment (SATA) interface, a parallel advanced technology attachment (PATA) interface, a USB interface, a serial attached small computer system (SAS) interface, a PCI-E interface, or a nonvolatile memory-express (NVMe) interface. However, embodiments are not limited thereto.

The processor 1120 may analyze a signal input to the storage device 1000 (in FIG. 8), and may process an operation according to a result of the analysis. The processor 1120 may control operations, such as data read, write, and erase operations, of the buffer memory 1150 and the nonvolatile memory device 1200 (in FIG. 8). The processor 1120 may include an MCU or a CPU. The processor 1120 may be a component included in the controller 111 of FIG. 2.

The processor 1120 may control the overall operation of the storage device 1000 (in FIG. 8) by using firmware FW. The firmware FW may refer to software, an application, etc. that process data in response to a user's input. The processor 1120 may execute the firmware FW to control the nonvolatile memory devices 1200 (in FIG. 8) and the power supply 1300 (in FIG. 8). Although the firmware FW is described as being executed in the processor 1120, embodiments are not limited thereto, and the firmware FW may be executed in the buffer memory 1150 or in another block configuration.

The processor 1120 may control the buffer memory 1150 to temporarily store data read from the nonvolatile memory devices 1200 (in FIG. 8) before providing the data to the host 2000 (in FIG. 8). In addition, the processor 1120 may control the buffer memory 1150 to temporarily store data requested by the host 2000 (in FIG. 8) to be written to the nonvolatile memory devices 1200 (in FIG. 8) before writing the data to the nonvolatile memory devices 1200 (in FIG. 8). In this regard, data provided to the host 2000 (in FIG. 8) or data provided from the host 2000 (in FIG. 8) may include data executed by an application and metadata of the host 2000 (in FIG. 8) for managing data.

The processor 1120 may control the power supply 1300 (in FIG. 8) to operate in an external power supply mode or an auxiliary power supply mode, in response to the SPO detection signal S_DET (in FIG. 8) received from the power supply 1300 (in FIG. 8). The processor 1120 may control the nonvolatile memory devices 1200 (in FIG. 8) to perform a dump operation, based on the SPO detection signal S_DET (in FIG. 8) received from the power supply 1300 (in FIG. 8).

The firmware FW may correspond to the firmware 114 of FIG. 2.

The memory interface 1140 may write data to the buffer memory 1150 or read data stored in the buffer memory 1150 under control by the processor 1120. The memory interface 1140 may include a buffer allocation unit (BAU) for managing a buffer, and may manage the use and release of a buffer.

The buffer memory 1150 may be used as a data storage medium of the controller 1100. The buffer memory 1150 may temporarily store data input/output to/from the nonvolatile memory devices 1200 (in FIG. 8) or the controller 1100. Data temporarily stored in the buffer memory 1150 may be transmitted to the host 2000 (in FIG. 8) or the nonvolatile memory devices 1200 (in FIG. 8) under control by the controller 1100. The buffer memory 1150 may include a volatile memory. For example, the buffer memory 1150 may include at least one of SRAM and DRAM. The buffer memory 1150 may correspond to the first memory 112 of FIG. 2.

The memory controller 1160 may control operations of the nonvolatile memory devices 1200 (in FIG. 8). The memory controller 1160 may exchange commands, addresses, data, etc. with the nonvolatile memory devices 1200 (in FIG. 8). For example, the memory controller 1160 may transmit signals received from the host interface 1110 to the nonvolatile memory devices 1200 (in FIG. 8) during a write operation, and may transmit signals read from the nonvolatile memory devices 1200 (in FIG. 8) to the host interface 1110 during a read operation.

The user interface 1170 may include an input interface through which a user may access the storage device 1000 (in FIG. 8) and an output interface capable of providing the user with an operation status or a processing result of the storage device 1000 (in FIG. 8). The user may learn through the user interface 1170 that the auxiliary power supply 1320 (in FIG. 8) of the storage device 100 is operating in a fail mode.

The bus 1180 may be a path for moving data between components included in the storage device 100. For example, the host interface 1110, the processor 1120, the ADC 1130, the memory interface 1140, the buffer memory 1150, the memory controller 1160, and the user interface 1170 may exchange signals with each other through the bus 1180.

According to one or more embodiments, a value of preset electrical energy to be stored in the auxiliary power supply 1320 may be adjusted based on information about first required energy according to process variability, a value of electrical energy to be stored in the auxiliary power supply 1320 or a value of the second required energy may be adjusted based on information about second required energy for a temperature and required performance of the main system 110, and when the adjusted value of the electrical energy or the adjusted value of the second required energy is greater than a value of available energy of the auxiliary power supply 1320, the signal Fail_Mode indicating that ‘the auxiliary power supply 1320 operates in a fail mode’ may be provided to the controller 1100, thereby improving the reliability of an operation of the storage device 1000.

While certain embodiments of the disclosure has been particularly shown and described, it will be understood that various changes in form and details may be made therein without departing from the spirit and scope of the following claims.

What is claimed is:

1. An operating method of a storage device comprising an auxiliary power supply, the operating method comprising:
adjusting a value of preset electrical energy to be stored in the auxiliary power supply, based on information about first required energy according to process variability of a main system;
adjusting a value of electrical energy to be stored in the auxiliary power supply or a value of second required energy, based on information about the second required energy for a temperature of the main system and a required performance of the main system, to obtain an adjusted value of the electrical energy or an adjusted value of the second required energy; and
based on the adjusted value of the electrical energy or the adjusted value of the second required energy being greater than a value of available energy of the auxiliary power supply, outputting a signal indicating that the auxiliary power supply operates in a fail mode.

2. The operating method of claim 1, wherein the first required energy represents minimum energy required for the main system to operate in an idle state at a first temperature,
wherein the second required energy represents minimum energy required for the main system to perform a first operation at a second temperature, and
wherein a value of the second temperature is greater than a value of the first temperature.

3. The operating method of claim 1, wherein the adjusting the value of the preset electrical energy to be stored in the auxiliary power supply comprises:
comparing a largest value among values of a plurality of first required energies according to the process variability of the main system with the value of the preset electrical energy to be stored in the auxiliary power supply; and
based on the largest value among the values of the plurality of first required energies being greater than the value of the preset electrical energy, changing the value of the electrical energy to be stored in the auxiliary power supply to the largest value among the values of the plurality of first required energies by adjusting a charging voltage of the auxiliary power supply.

4. The operating method of claim 1, wherein the adjusting of the value of the electrical energy to be stored in the auxiliary power supply or the value of the second required energy comprises:
requesting information about required energy of the main system at a second temperature from the main system, based on temperature measurement information of a temperature sensor;
receiving the information about the second required energy that is minimum energy required for the main system to perform a first operation at the second temperature; and
comparing the value of the second required energy with the value of the electrical energy to be stored in the auxiliary power supply.

5. The operating method of claim 4, wherein the adjusting the value of the electrical energy to be stored in the auxiliary power supply or the value of the second required energy further comprises, based on the value of the second required energy being greater than the value of the electrical energy to be stored in the auxiliary power supply, increasing the value of the electrical energy to be stored in the auxiliary power supply to correspond to the value of the second required energy by adjusting a charging voltage of the auxiliary power supply.

6. The operating method of claim 4, wherein the adjusting the value of the electrical energy to be stored in the auxiliary power supply or the value of the second required energy further comprises, based on the value of the second required energy being greater than the value of the electrical energy to be stored in the auxiliary power supply, reducing the value of the second required energy by adjusting a level of a voltage required for a load in the main system.

7. The operating method of claim 1, wherein the fail mode represents a state in which a power supply is unable to provide auxiliary power to the main system through the auxiliary power supply based on a sudden power-off occurring.

8. A storage device comprising:
an auxiliary power supply configured to provide auxiliary power;
a power supply comprising a power controller configured to output an output voltage based on external power or the auxiliary power;
a temperature sensor configured to measure a temperature of a main system;
a controller configured to output information about required energy of the main system; and
a correction circuit configured to:
adjust a value of preset electrical energy to be stored in the auxiliary power supply, based on information about first required energy according to process variability of the main system;
adjust a value of electrical energy to be stored in the auxiliary power supply or a value of second required energy, based on information about the second required energy for the temperature of the main system and a required performance of the main system, to generate an adjusted value of the electrical energy or an adjusted value of the second required energy; and
based on the adjusted value of the electrical energy or the adjusted value of the second required energy being greater than a value of available energy of the auxiliary power supply, output a signal indicating that the auxiliary power supply operates in a fail mode to the controller.

9. The storage device of claim 8,
wherein the first required energy represents minimum energy required for the main system to operate in an idle state at a first temperature,
wherein the second required energy represents minimum energy required for the main system to perform a first operation at a second temperature, and
wherein a value of the second temperature is greater than a value of the first temperature.

10. The storage device of claim 8, wherein the correction circuit is further configured to:
compare a largest value among values of a plurality of first required energies according to the process variability of the main system with the value of the preset electrical energy to be stored in the auxiliary power supply; and
based on the largest value among the values of the plurality of first required energies being greater than the value of the preset electrical energy, change the value of the electrical energy to be stored in the auxiliary power supply to the largest value among the values of the plurality of first required energies by adjusting a charging voltage of the auxiliary power supply.

11. The storage device of claim 8, wherein the correction circuit is further configured to:
request information about required energy of the main system at a second temperature from the main system, based on temperature measurement information of the temperature sensor;
receive the information about the second required energy that is minimum energy required for the main system to perform a first operation at the second temperature; and
compare the value of the second required energy with the value of the electrical energy to be stored in the auxiliary power supply.

12. The storage device of claim 11, wherein the correction circuit is further configured to, based on the value of the second required energy being greater than the value of the electrical energy to be stored in the auxiliary power supply, increase the value of the electrical energy to be stored in the auxiliary power supply to correspond to the value of the second required energy by adjusting a charging voltage of the auxiliary power supply.

13. The storage device of claim 11, wherein the correction circuit is further configured to, based on the value of the second required energy being greater than the value of the electrical energy to be stored in the auxiliary power supply, reduce the value of the second required energy by adjusting a level of a voltage required for a load in the main system.

14. The storage device of claim 8, wherein the fail mode represents a state in which the power supply is unable to provide the auxiliary power to the main system through the auxiliary power supply based on a sudden power-off occurring.

15. A storage device comprising:
an auxiliary power supply configured to provide auxiliary power;
a power supply comprising a power controller configured to output an output voltage based on external power or the auxiliary power;
a temperature sensor configured to measure a temperature of a main system;
the main system configured to operate based on the output voltage and perform a dump operation of backing up data based on a sudden power-off occurring; and
a correction circuit configured to:
adjust a value of preset electrical energy to be stored in the auxiliary power supply, based on information about first required energy according to process variability of the main system;
adjust a value of electrical energy to be stored in the auxiliary power supply or a value of second required energy, based on information about the second required energy for the temperature of the main system and a required performance of the main system, to obtain an adjusted value of the electrical energy or an adjusted value of the second required energy; and
based on the adjusted value of the electrical energy or the adjusted value of the second required energy being greater than a value of available energy of the auxiliary power supply, output a signal indicating that the auxiliary power supply operates in a fail mode to the main system.

16. The storage device of claim 15, wherein the first required energy represents minimum energy required for the main system to operate in an idle state at a first temperature,
wherein the second required energy represents minimum energy required for the main system to perform a first operation at a second temperature, and
wherein a value of the second temperature is greater than a value of the first temperature.

17. The storage device of claim 15, wherein the correction circuit is further configured to:
compare a largest value among values of a plurality of first required energies according to the process variability of the main system with the value of the preset electrical energy to be stored in the auxiliary power supply; and
based on the largest value among the values of the plurality of first required energies being greater than the value of the preset electrical energy, change the value of the electrical energy to be stored in the auxiliary power supply to the largest value among the values of the plurality of first required energies by adjusting a charging voltage of the auxiliary power supply.

18. The storage device of claim 15, wherein the correction circuit is further configured to:
request information about required energy of the main system at a second temperature from the main system, based on temperature measurement information of the temperature sensor;
receive the information about the second required energy that is minimum energy required for the main system to perform a first operation at the second temperature; and
compare the value of the second required energy with the value of the electrical energy to be stored in the auxiliary power supply.

19. The storage device of claim 18, wherein the correction circuit is further configured to, based on the value of the second required energy being greater than the value of the electrical energy to be stored in the auxiliary power supply, increase the value of the electrical energy to be stored in the auxiliary power supply to correspond to the value of the second required energy by adjusting a charging voltage of the auxiliary power supply.

20. The storage device of claim 15, wherein the fail mode represents a state in which the power supply is unable to provide the auxiliary power to the main system through the auxiliary power supply based on the sudden power-off occurring.
